(19) United States
(12) Patent Application Publication
(10) Pub. No.: US 2018/0267369 A1
(43) Pub. Date: Sep. 20, 2018

(54) ARRAY SUBSTRATE AND LIQUID CRYSTAL DISPLAY PANEL

(71) Applicant: Shenzhen China Star Optoelectronics Technology Co., Ltd., Shenzhen, Guangdong (CN)

(72) Inventor: Wanliang ZHOU, Shenzhen, Guangdong (CN)

(73) Assignee: Shenzhen China Star Optoelectronics Technology Co., Ltd., Shenzhen, Guangdong (CN)

(21) Appl. No.: 15/544,517

(22) PCT Filed: Mar. 7, 2017
(86) PCT No.: PCT/CN2017/075847

§ 371 Date: Jul. 18, 2017

(30) Foreign Application Priority Data
Feb. 22, 2017 (CN) 201710094814.X

(51) Int. Cl. G02F 1/1343; G02F 1/1335; G02F 1/1368; H01L 29/786

(52) U.S. Cl. CPC G02F 1/134309; G02F 1/133512; G02F 2202/104; G02F 1/133514; H01L 29/78621; G02F 1/1368

(57) ABSTRACT

The disclosure provides an array substrate, including a glass substrate. The glass substrate is deposited with a source electrode and a drain electrode on an identical layer. The source electrode and the drain electrode are disposed with a plane. The plane is disposed with a first common electrode. The first common electrode is covered by a dielectric layer. The dielectric layer is respectively disposed with pixel electrodes and second common electrodes. The pixel electrodes and the drain electrode are connected through a via hole in the dielectric layer. The disclosure further discloses a liquid crystal display panel, including a color filter substrate. The color filter substrate includes a black matrix, and the array substrate. The second common electrodes are disposed correspondingly to the black matrix. Compared with the prior art, the second common electrodes are disposed around the pixel electrodes to increase the transmittance around the pixel electrodes.

### TECHNICAL FIELD

The disclosure relates to a display technical field, and more particularly to an array substrate and a liquid crystal display panel.

### DESCRIPTION OF RELATED ART

A low temperature poly-silicon thin film transistor liquid crystal display (LTPS-TFT LCD) has advantages such as high resolution, quick response, high brightness and aperture ratio compared with a conventional amorphous silicon thin film transistor liquid crystal display. Therefore, the LTPS-TFT LCD is applied more and more widely.

In the point inversion or column inversion driving method of the conventional LTPS-TFT LCD, as polarities of digital signals between a subpixel and an adjacent subpixel are contrary, severe in-plane switching (IPS) generally occurs to generate a push mura phenomenon. Panels engender unrecoverable mottle after being attacked by external force. A conventional solution is increasing the distance among adjacent subpixels to prevent them from being too close, but it can bring a problem that transmittance among adjacent subpixels is lower than transmittance in other positions. The large space around pixels with high resolution leads to reduction of transmittance of the entire liquid crystal display panel.

### SUMMARY

In order to overcome shortcomings of the prior art, the disclosure provides an array substrate and a liquid crystal display panel to enhance transmittance.

The disclosure provides an array substrate, including a glass substrate. The glass substrate is deposited with a source electrode and a drain electrode on an identical layer. The source electrode and the drain electrode are disposed with a plane. The plane is disposed with a first common electrode. The first common electrode is covered by a dielectric layer. The dielectric layer is respectively disposed with pixel electrodes and second common electrodes. The pixel electrodes and the drain electrode are connected through a via hole in the dielectric layer.

In an embodiment of the disclosure, the pixel electrodes and the second common electrodes are disposed on an identical layer.

In an embodiment of the disclosure, a voltage of the second common electrodes is adjustable.

In an embodiment of the disclosure, the second common electrodes encompass each of the pixel electrodes. Two adjacent second common electrodes are connected mutually.

In an embodiment of the disclosure, distances between edges of the pixel electrodes and the second common electrodes are the same.

In an embodiment of the disclosure, the second common electrodes are rectangular.

In an embodiment of the disclosure, a shape of the second common electrodes varies along with a shape of the pixel electrodes.

In an embodiment of the disclosure, material to produce the first common electrode and material to produce the second common electrodes are identical.

The disclosure further discloses a liquid crystal display panel, including a color filter substrate. The color filter substrate includes a black matrix, and the array substrate. The second common electrodes are disposed correspondingly to the black matrix.

In an embodiment of the disclosure, a width of the second common electrodes is less than or equal to a width of the black matrix.

Compared with the prior art, the disclosure disposes the second common electrodes around the pixel electrodes to increase the transmittance around the pixel electrodes, and the position thereof and that of the black matrix are corresponding, which will not affect the aperture ratio.

### BRIEF DESCRIPTION OF THE DRAWINGS

FIG. 1 is a structural schematic view of a liquid crystal panel according to the disclosure.

FIG. 2 is a schematic view of a first disposition form of second common electrodes according to the disclosure.

FIG. 3 is a schematic view of a second disposition form of second common electrodes according to the disclosure.

FIG. 4-1 is a schematic view of step one in a manufacturing process according to the disclosure.

FIG. 4-2 is a schematic view of step two in a manufacturing process according to the disclosure.

FIG. 4-3 is a schematic view of step three in a manufacturing process according to the disclosure.

FIG. 4-4 is a schematic view of step four in a manufacturing process according to the disclosure.

FIG. 4-5 is a schematic view of step five in a manufacturing process according to the disclosure.

FIG. 4-6 is a schematic view of step six in a manufacturing process according to the disclosure.

FIG. 4-7 is a schematic view of step seven in a manufacturing process according to the disclosure.

FIG. 4-8 is a schematic view of step eight in a manufacturing process according to the disclosure.

FIG. 4-9 is a schematic view of step nine in a manufacturing process according to the disclosure.

FIG. 4-10 is a schematic view of step ten in a manufacturing process according to the disclosure.

FIG. 4-11 is a schematic view of step eleven in a manufacturing process according to the disclosure.

### DETAILED DESCRIPTION OF PREFERRED EMBODIMENTS

The disclosure will be described in detail with reference to embodiments and the accompanying drawings as follows.

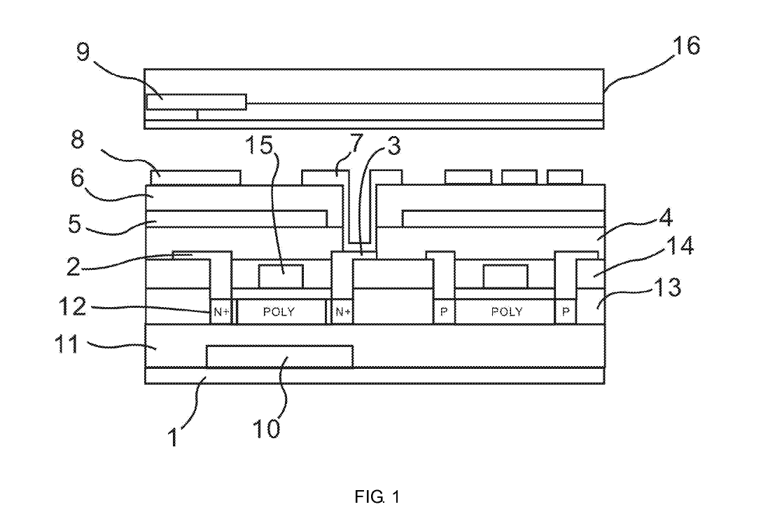

As shown in FIG. 1, the figure shows two sections of an array substrate of the disclosure. The left section is a display region of the array substrate. The right section is a circuit driving region of the array substrate. The array substrate includes a glass substrate 1, and a light shelter (LS) layer 10 disposed on the glass substrate 1. The LS layer 10 is disposed with a buffer layer 11. The buffer layer 11 is disposed with a semiconductor layer 12 and a gate dielectric layer 13. The gate dielectric layer 13 is disposed with a gate electrode 15. The gate electrode 15 is covered by an inter-layer dielectric 14. The inter-layer dielectric 14 is disposed with a source electrode 2 and a drain electrode 3 on an identical layer. The source electrode 2 and the drain electrode 3 are connected with the semiconductor layer 12. The source electrode 2 and the drain electrode 3 are disposed with a plane (PLN) layer 4. The PLN layer 4 is disposed with a first common electrode 5. The first common electrode 5 is covered by a dielectric layer 6. The dielectric layer 6 is respectively disposed with pixel electrodes 7 and second common electrodes 8. The pixel electrodes 7 and the second common electrodes 8 are disposed on the same layer and adopt the same material with the first common electrode 5, which is indium tin oxide (ITO). The pixel electrodes 7 and the drain electrode 3 are connected through a via hole in the dielectric layer. The second common electrodes 8 encompass each of the pixel electrodes 7. Two adjacent second common electrodes 8 are connected mutually to enhance transmittance around the pixel electrodes 7 and uniformity of light penetration, as well as reducing costs of production. The semiconductor layer in the display region is an NMOS transistor. The semiconductor layer in the circuit driving region is a PMOS transistor.

The voltage of the second common electrodes 8 can be adjusted to be different from the voltage of the first common electrode 5 according to the requirement of products, the function thereof is to improve redirection efficiency of liquid crystal on edge of pixels and uniformity of light penetration, resulting in the effect of enhancing transmittance of panels.

Specifically, distances between edges of the pixel electrodes 7 and the second common electrodes 8 are the same.

A manufacturing method of an array substrate of the disclosure includes following steps.

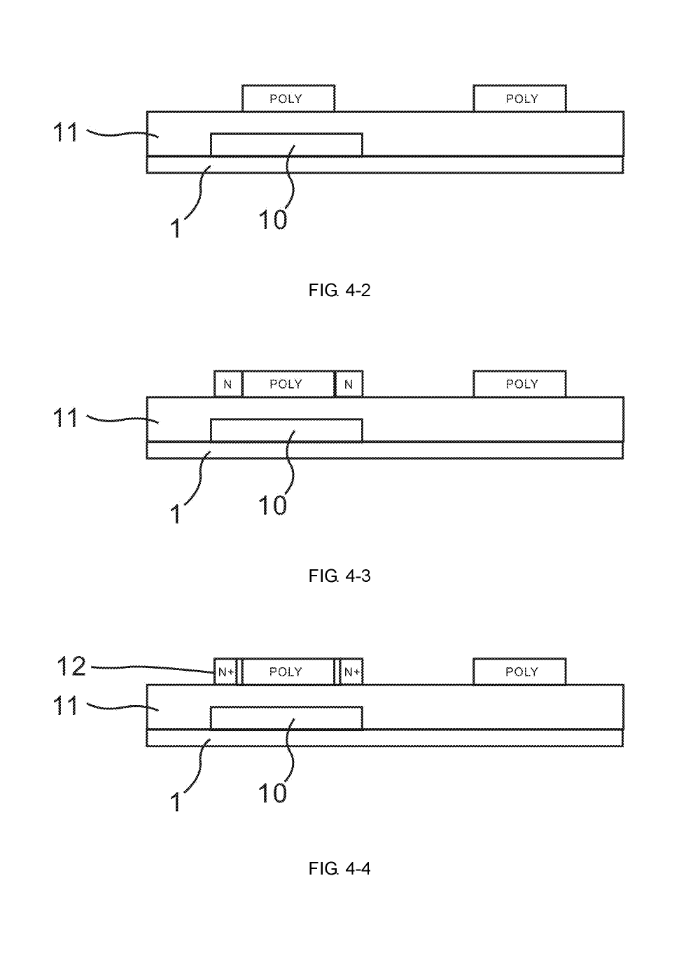

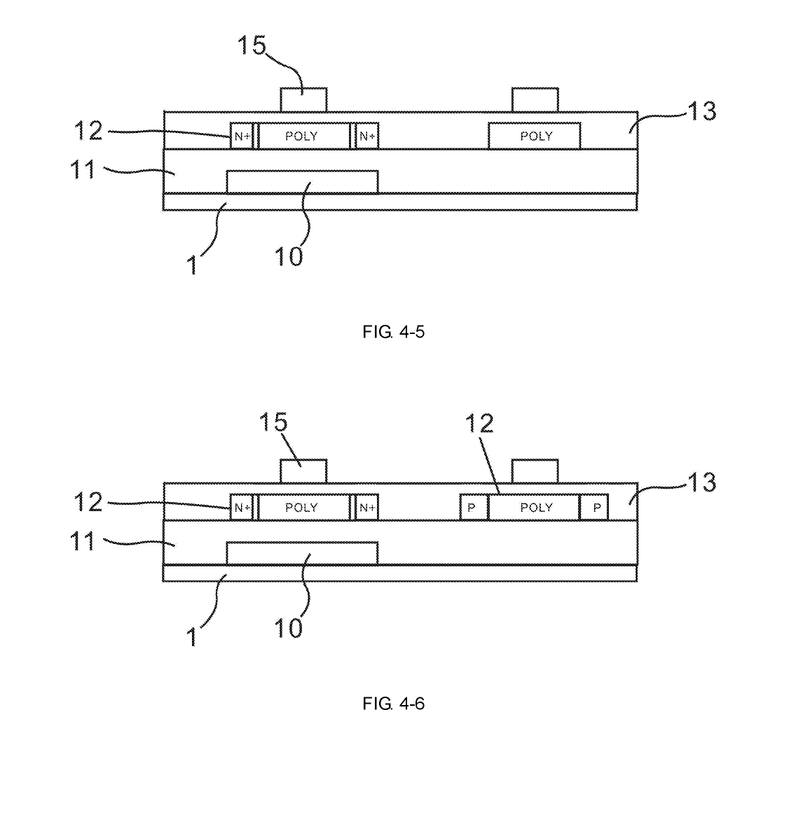

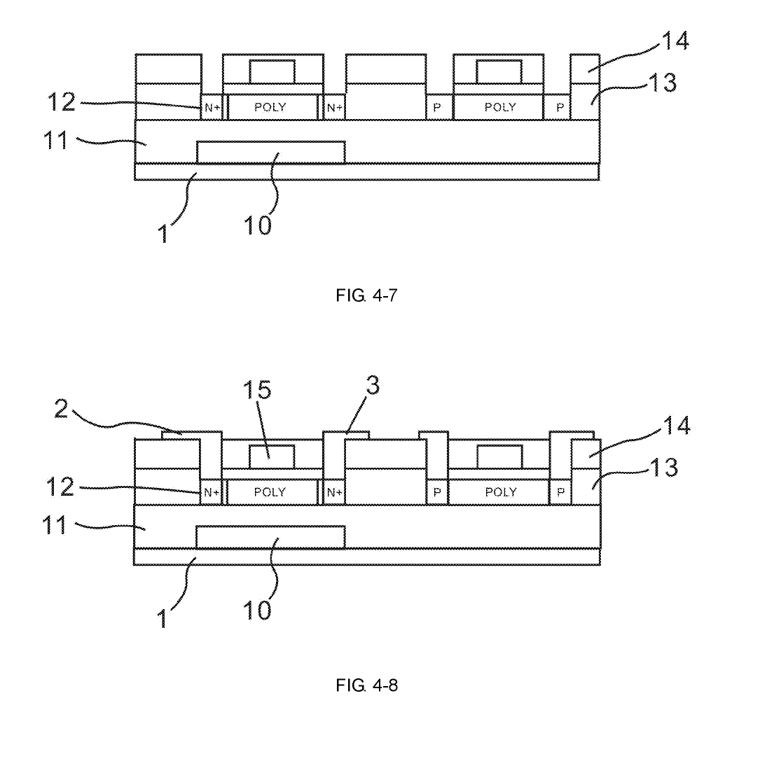

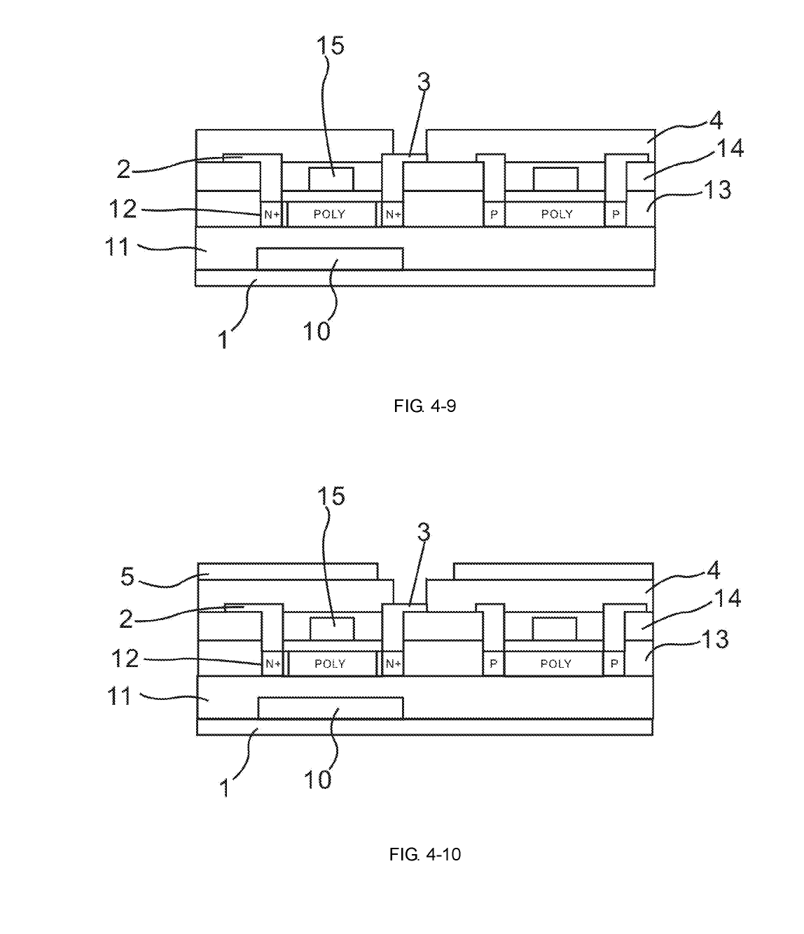

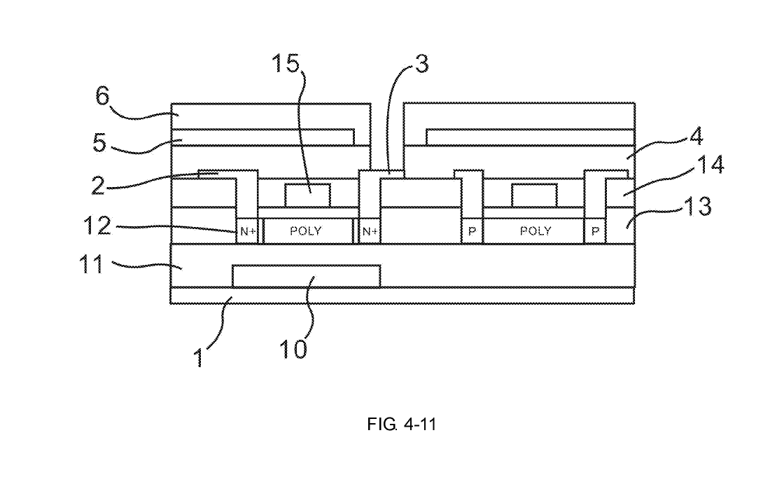

Step one, as shown in FIG. 4-1, providing the glass substrate 1, forming MO/Al on the glass substrate 1 by physical vapor deposition (PVD) and patterning MO/Al to form the light shelter (LS) layer 10.

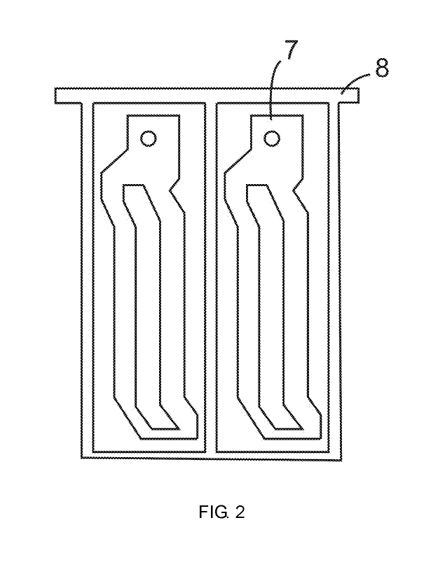

Step two, as shown in FIG. 4-2, covering a layer of buffer layer 11 on the glass substrate 1 and the LS layer 10, processing an A-Si semiconductor layer to form polycrystalline silicon on the buffer layer 11 and patterning the polycrystalline silicon. The buffer layer 11 is SiOx/SiNx.

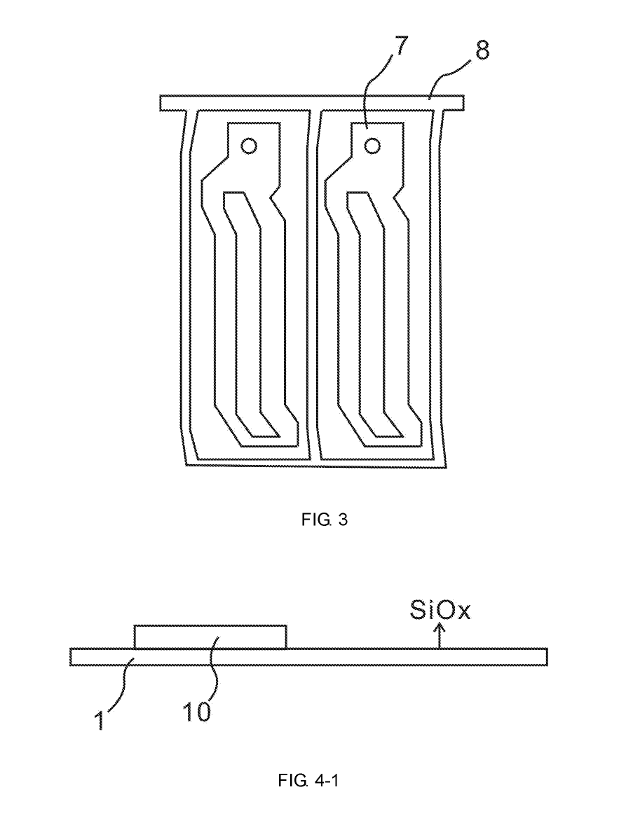

Step three, as shown in FIG. 4-3, doping the polycrystalline silicon in the display region with N ions by chemical vapor deposition.

Step four, as shown in FIG. 4-4, heavily doping a groove of polycrystalline silicon doped with N ions with N ions to form the semiconductor layer 12 of the display region of lightly doped drain (LDD). The semiconductor layer 12 of the display region is disposed above the LS layer 10.

Step five, as shown in FIG. 4-5, forming the gate dielectric layer 13 on the semiconductor layer 12 of the display region and the polycrystalline silicon on the circuit driving region, forming an electrode wire (gate electrode 15) on the gate dielectric layer 13.

Step six, as shown in FIG. 4-6, doping the polycrystalline silicon of the circuit driving region with P ions to form PMOS (the semiconductor layer 12 of the circuit driving region).

Step seven, as shown in FIG. 4-7, producing a layer of inter-layer dielectric (ILD) 14 on the gate electrode 15, and preparing the via hole in the N+ region and the P region of the semiconductor layer 12 on the ILD 14.

Step eight, as shown in FIG. 4-8, forming the source electrode 2 and the drain electrode 3 on the ILD 14, and connecting with the N+ region and the P region of the semiconductor layer 12 through the via hole.

Step nine, as shown in FIG. 4-9, producing the plane (PLN) 4 on the source electrode 2 and the drain electrode 3 by a photoetching (PHT) process, and forming a PLN via hole in the drain electrode of the display region.

Step ten, as shown in FIG. 4-10, forming the first common electrode 5 after forming and patterning an ITO (transparent conductive) layer on the PLN 4, forming a first common electrode via hole in the first common electrode 5 on the PLN via hole.

Step eleven, as shown in FIG. 4-11, forming a dielectric layer (PV) 6 on the first common electrode 5, and forming a PV via hole on the first common electrode via hole.

Step twelve, as shown in FIG. 1, forming the pixel electrodes 7 and the second common electrodes 8 after forming and patterning an ITO (transparent conductive) layer by PVD on the dielectric layer 6. The pixel electrodes 7 and the drain electrode 3 in the display region are connected through the PV via hole, the first common electrode via hole and the PLN via hole to obtain the array substrate. The first common electrode 5 and the second common electrodes 8 in the disclosure are produced by transparent electrode material such as ITO (transparent conductive) or so on.

As shown in FIG. 1, a liquid crystal display panel of the disclosure includes a color filter substrate 16. The color filter substrate 16 in the disclosure is a color filter substrate in the prior art. The color filter substrate 16 includes a black matrix 9. The liquid crystal display panel further includes the array substrate described above. The second common electrodes 8 are disposed correspondingly to the black matrix 9. The width of the second common electrodes 8 is less than or equal to the width of the black matrix 9, which will not affect the aperture ratio.

As shown in FIG. 2, the second common electrodes 8 are rectangular.

As shown in FIG. 3, a shape of the second common electrodes 8 varies along with a shape of the pixel electrodes 7. The width of the shape is less than the width of the black matrix. It can be seen from the figure that margins of the second common electrodes 8 adjacent to the right and left of the pixel electrodes 7 match the outline of right and left of the pixel electrodes 7. Upper and bottom parts on right and left sides of the pixel electrodes 7 in FIG. 3 lean to the right to form two slopes. Protrusion slightly towards the left is formed on the corresponding position on the side of the second common electrodes 8. The protrusion does not exceed the width of the black matrix. The form can coordinate with shape variation of the pixel electrodes 7.

Although the disclosure is illustrated with reference to specific embodiments, a person skilled in the art should understand that various modifications on forms and details can be achieved within the spirit and scope of the disclosure limited by the claims and the counterpart.

What is claimed is:

1. An array substrate, comprising a glass substrate, the glass substrate deposited with a source electrode and a drain electrode on an identical layer, the source electrode and the drain electrode disposed with a plane, the plane disposed with a first common electrode, the first common electrode covered by a dielectric layer, the dielectric layer respectively disposed with pixel electrodes and second common electrodes, the pixel electrodes and the drain electrode connected through a via hole in the dielectric layer.

2. The array substrate according to claim 1, wherein the pixel electrodes and the second common electrodes are disposed on an identical layer.

3. The array substrate according to claim 1, wherein a voltage of the second common electrodes is adjustable.

4. The array substrate according to claim 1, wherein the second common electrodes encompass each of the pixel electrodes, two adjacent second common electrodes are connected mutually.

5. The array substrate according to claim 4, wherein distances between edges of the pixel electrodes and the second common electrodes are the same.

6. The array substrate according to claim 5, wherein the second common electrodes are rectangular.

7. The array substrate according to claim 5, wherein a shape of the second common electrodes varies along with a shape of the pixel electrodes.

8. The array substrate according to claim 6, wherein material to produce the first common electrode and material to produce the second common electrodes are identical.

9. The array substrate according to claim 7, wherein material to produce the first common electrode and material to produce the second common electrodes are identical.

10. A liquid crystal display panel, comprising a color filter substrate, the color filter substrate comprising a black matrix, and an array substrate, the array substrate comprising a glass substrate, the glass substrate disposed with a source electrode and a drain electrode on an identical layer, the source electrode and the drain electrode disposed with a plane, the plane disposed with a first common electrode, the first common electrode covered by a dielectric layer, the dielectric layer respectively disposed with pixel electrodes and second common electrodes, the pixel electrodes and the drain electrode connected through a via hole in the dielectric layer; the second common electrodes disposed correspondingly to the black matrix.

11. The liquid crystal display panel according to claim 10, wherein the pixel electrodes and the second common electrodes are disposed on an identical layer.

12. The liquid crystal display panel according to claim 10, wherein a voltage of the second common electrodes is adjustable.

13. The liquid crystal display panel according to claim 10, wherein the second common electrodes encompass each of the pixel electrodes, two adjacent second common electrodes are connected mutually.

14. The liquid crystal display panel according to claim 13, wherein distances between edges of the pixel electrodes and the second common electrodes are the same.

15. The liquid crystal display panel according to claim 14, wherein the second common electrodes are rectangular.

16. The liquid crystal display panel according to claim 14, wherein a shape of the second common electrodes varies along with a shape of the pixel electrodes.

17. The liquid crystal display panel according to claim 10, wherein a width of the second common electrodes is less than or equal to a width of the black matrix.
